(19) United States
(12) Patent Application Publication
(10) Pub. No.: US 2002/0036099 A1
(43) Pub. Date: Mar. 28, 2002

(54) Circuit board for transmitting signals, method for producing the same, and electronic device having the same

(75) Inventor: Shogo Hachiya, Tokyo (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 09/963,640

(22) Filed: Sep. 27, 2001

(30) Foreign Application Priority Data
Sep. 28, 2000 (JP) 2000-296362

(51) Int. Cl. H05K 1/03

(52) U.S. Cl. 174/255

(57) ABSTRACT

A circuit card for transmitting signals having one or more long and narrow holes in a ground/power supply plane under a pad, which is connected to a pattern, the hole extending in a direction substantially parallel with a direction of the pattern extending away from the pad. The holes are sized and positioned to substantially minimize a mismatch of impedance between the pad and the pattern so that reflection of transmission signals caused by impedance mismatch can be suppressed.

### CROSS-REFERENCE TO RELATED APPLICATIONS

This application is based upon and claims the benefit of priority from prior Japanese Patent Application No. 2000-296362, filed on Sep. 28, 2000, the entire contents of which are incorporated herein by reference.

### FIELD OF THE INVENTION

The invention relates to a circuit board for transmitting signals. More particularly, the invention relates to a circuit board for transmitting high-speed signals, a method for manufacturing the circuit board, and an electronic device mounting the circuit board.

### BACKGROUND

To execute normal signal transmission on a circuit board for transmitting high-speed signals, it is necessary to design the impedance in any position on the transmission line (hereinafter, referred to as ‘pattern’) to be equal. Local impedance that is not matched can cause an error in signal transmission. Particularly, a connection pad and a pad for mounting parts (hereinafter, generically referred to as ‘pad’) formed on or at the end of the pattern are wider in width than the pattern. As a result, the impedance decreases at the pad as compared with that of the pattern. This impedance mismatch causes reflection of a transmission signal and deterioration in the transmission integrity of the high-speed signals (also called ‘signal integrity’).

In consideration of such a condition, Japanese laid-open patent publication No. 6-260773 discloses a circuit board for transmitting high-speed signals, wherein the circuit board has a rectangular hole in a ground/power supply plane below a pad to avoid an impedance mismatch. In the circuit board, the amount of overlap of the pad and the ground/power supply plane is adjustable in the direction in which the pattern leads or extends from the pad.

According to the publication, the hole is formed in the ground/power supply plane partially below the pad to make the thicknesses of the dielectric layers, namely, the distance between the pad and a lower ground/power supply plane, different from that of the surrounding area. In this manner, the impedance matching is performed by adjusting the ratio of an area having the hole below the pad and an area without the hole below the pad to make the impedance at the pad as a whole equal to that of the pattern on a lumped parameter basis. As a result, suppression of the reflection of the transmission signal waveform is suppressed and the integrity of high-speed signals is improved.

High-speed signals are handled on a distributed parameter basis in consideration of continuity. However, in the structure disclosed in the publication, the impedance at the pad is understood on a lumped parameter basis and the rectangular hole is formed with its long direction perpendicular to the direction in which the pattern extends from the pad. The impedance locally changes because the layer constitution, such as the thickness of the surface layer pattern, changes along the travel direction of transmission signals. Therefore, impedance mismatch occurs at the portion where the layer constitution changes, such as at the beginning of the hole or a junction of the pattern and the pad. A reflected wave caused by this impedance mismatch generates noise in the waveform of the transmission signal.

### SUMMARY

In accordance with an embodiment of the invention, there is provided a circuit board for transmitting signals. The circuit board comprises: a dielectric layer; a signal line configured as a pattern on the dielectric layer to transmit the signals; a pad formed on the dielectric layer, the pattern connected to and extending away from the pad; and a ground/power supply layer formed under the dielectric layer and having a hole below the pad, the hole extending in a direction substantially parallel with a direction oft he pattern extending away from the pad.

Also in accordance with an embodiment of the invention, there is provided a method for producing a circuit board for transmitting signals. The method comprises forming a dielectric layer; forming a signal line configured to transmit the signals, patterned on the dielectric layer; forming a pad on the dielectric layer and connected to the pattern; and forming a ground/power supply layer under the dielectric layer including a hole below the pad, the hole extending in a direction substantially parallel with a direction oft he pattern extending away from the pad.

Further in accordance with an embodiment of the invention, there is provided an electronic device comprising: a body for mounting circuit elements, and a circuit board mounted in the body and including a signal transmitting line on a surface thereof, the circuit board including: a dielectric layer having an upper surface and a lower surface; a pattern formed on the upper surface of the dielectric layer, the pattern comprising the signal transmission line via which signals are transmitted; a pad formed on the upper surface of the dielectric layer and connected to the pattern, the pad having a width wider than that of the pattern; and a ground/power supply layer formed on the lower surface of the dielectric layer and having at least one hole below the pad, the hole being rectangular and longer in a direction substantially parallel with a direction of the pattern extending away from the pad.

### BRIEF DESCRIPTION OF THE DRAWINGS

The accompanying drawings, which are incorporated in and constitute part of this specification, illustrate various embodiments and/or features of the invention and together with the description, serve to explain the principles of the invention. In the drawings:

FIG. 1(a) is a plan view showing structure in a neighborhood of a pad formed on a circuit board for transmitting signals consistent with a first embodiment of the present invention;

FIGS. 1(b) and (c) illustrate sections I-I and II-II, respectively, of the structure shown of FIG. 1 (a);

FIG. 2 is a plan view showing an example of the shape of a hole for impedance matching in the structure of FIG. 1(a);

FIG. 3(a) is a plan view showing the structure in a neighborhood of a pad formed on a circuit board for transmitting signals consistent with a second embodiment of the present invention;

FIGS. 3(b) and (c) illustrate sections III-III and IV-IV, respectively, oft he structure shown of FIG. 3(a);

FIG. 4(a) is a plan view showing the structure in a neighborhood of a pad formed on a circuit board for transmitting signals consistent with a third embodiment of the present invention;

FIGS. 4(b) and (c) illustrate sections V-V and VI-VI, respectively, oft he structure shown of FIG. 4(a);

FIG. 5(a) is a plan view showing the structure in a neighborhood of a pad formed on a circuit board for transmitting signals consistent with a fourth embodiment of the present invention;

FIGS. 5(b) and (c) illustrate sections VII-VII and VIII-VIII, respectively, of the structure shown of FIG. 5(a); and

FIG. 6 is a section showing a circuit board, mounted in a computer, for transmitting signals consistent with embodiments of the present invention.

### DETAILED DESCRIPTION

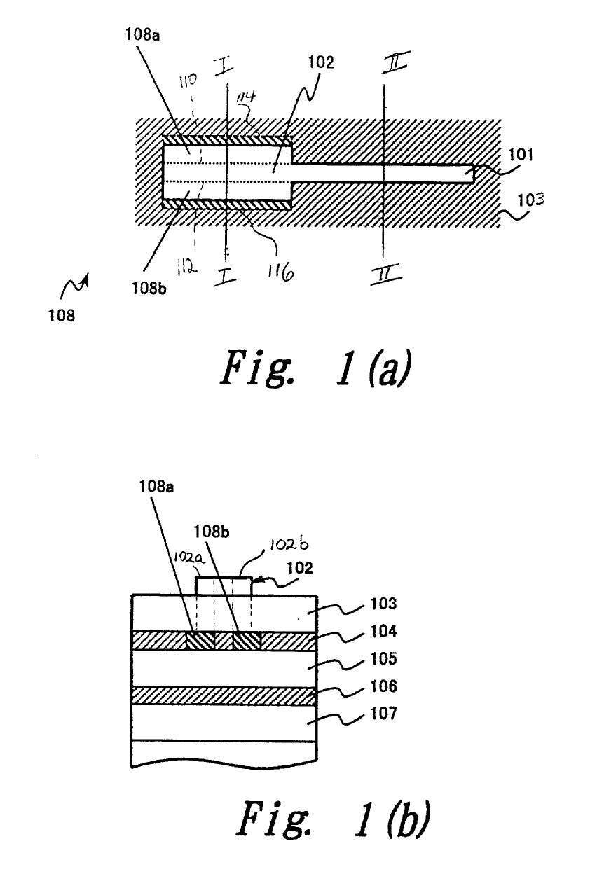

FIG. 1(a) is a plan view showing the structure in a neighborhood of a pad formed on a circuit board for transmitting signals consistent with a first embodiment of the present invention. FIGS. 1(b) and (c) are sections respectively taken along line I-I and II-II of FIG. 1(a).

With reference to FIGS. 1(a) to 1(c), a first layer is a transmission line layer composed of a surface layer pattern formed on a dielectric layer 103. The surface layer pattern includes a pattern 101 and a pad 102. A second layer is a ground and/or power supply layer composed of a ground/power supply plane 104 and a dielectric layer 105. A third layer is also a ground/power supply layer composed of a ground/power supply plane 106 and a dielectric layer 107. The dielectric layer 105 may be composed of two layers and may have a transmission line layer between those layers.

Because the pad 102 is wider in width than the pattern 101 and has a large area facing the ground/power supply plane 104, the capacitance of the pad 102 is larger and the impedance of the pad 102 is lower than those of the pattern 101. Therefore, it is necessary to reduce the capacitance of the pad 102 in order to increase its self-inductance and its impedance by reducing the area of the ground/power supply plane 104 below the pad 102. Changing the dielectric constant of the dielectric layer 103 or the pattern thickness of the pad 102 to reduce the capacitance is not necessarily realistic because manufacturing difficulties may be encountered in attempting to make such changes.

Therefore, a pair of holes 108 for impedance matching, e.g.,holes 108a and 108b, are formed in the ground/power supply plane 104 below the pad 102 along a direction substantially parallel with the direction of the pattern 101 leading or extending away from the pad 102. As shown in FIG. 1(b), portions 102a and 102b are located over the positions of the holes 108a and 108b. With regard to the portion of the pad having no hole 108 below it, the distance between the pad 102 and the ground/power supply plane 104 is the thickness of the dielectric layer 103. With regard to the portions 102a and 102b of the pad 102 having the holes 108a and 108b below them, the distance between the pad 102 and the ground/power supply plane 106 depends on the thickness of the dielectric layers 103 and 105 and the ground/power supply layer 104. Therefore, by adjusting the respective areas oft he holes 108a and 108b under the pad 102, it becomes possible to match the impedance of the pad 102 as a whole to that of the pattern 101.

According to this embodiment, because the holes 108a and 108b of the ground/power supply plane 104 are formed to be substantially parallel with the direction of the pattern 101 extending away from the pad 102, the reflection caused by impedance mismatch can be reduced. As seen in FIGS. 1(a)-1(c), each of the holes 108a and 108b is formed in the ground/power supply plane 104 below the pad 102 outside broken imaginary lines 110 and 112, respectively, made by extending the edges of the pattern 101. Further, as seen in FIGS. 1(a) and 1(b), including the broken lines in FIG. 1(b), outer edges 114 and 116 of holes 108(a) and 108(b), respectively, extend beyond the edges of pad 102.

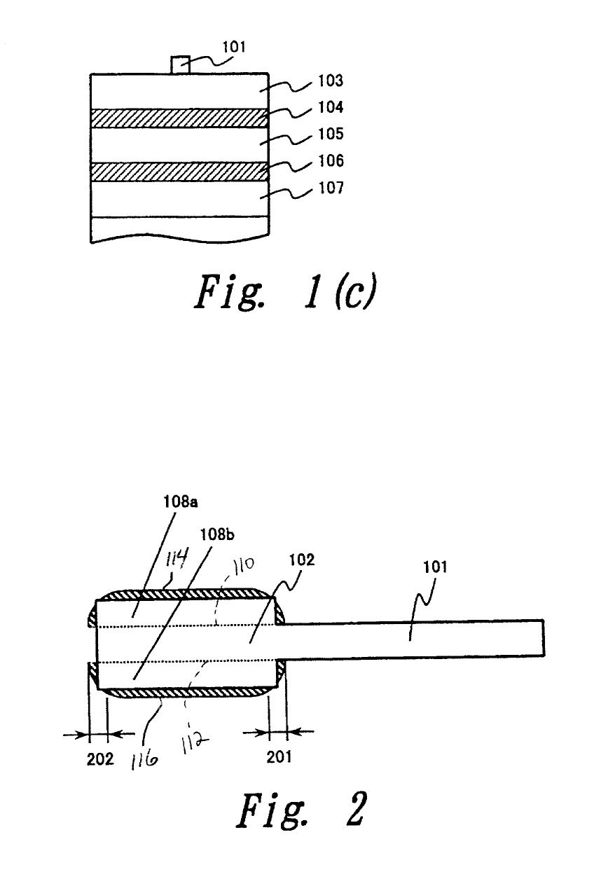

As illustrated in FIG. 2, when the electric lines of force are considered three-dimensionally, there is a possibility that reflection may be generated at a pad edge 202 or a junction 201 oft he pattern 101 and the pad 102. Therefore, as shown in FIG. 2, the shape of each hole 108a or 108b may be gradually spread in the direction of the width of the pad 102 around the junction 201, and be gradually narrowed to the width of the pattern 101 around the pad edge 202 remote from the junction of the pattern 101 and the pad 102. By doing this, the impedance mismatch at the junction 201 and the pad edge 202 can be further reduced.

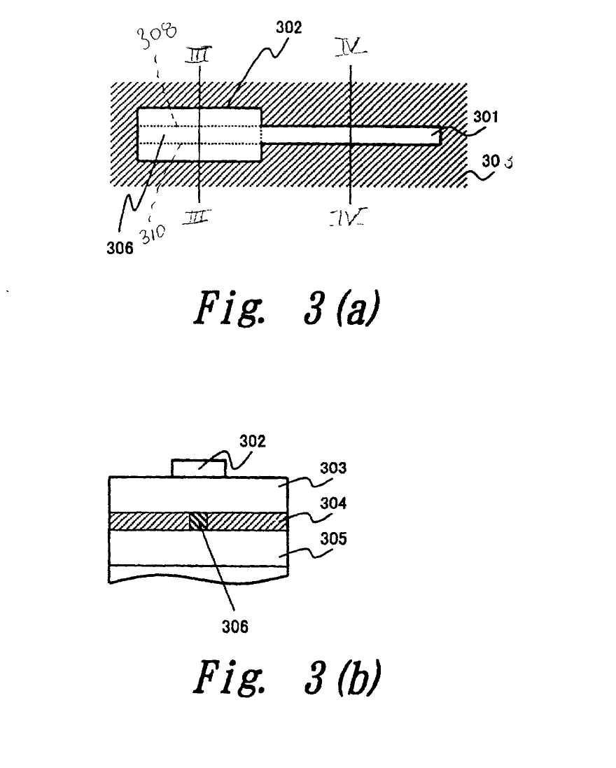

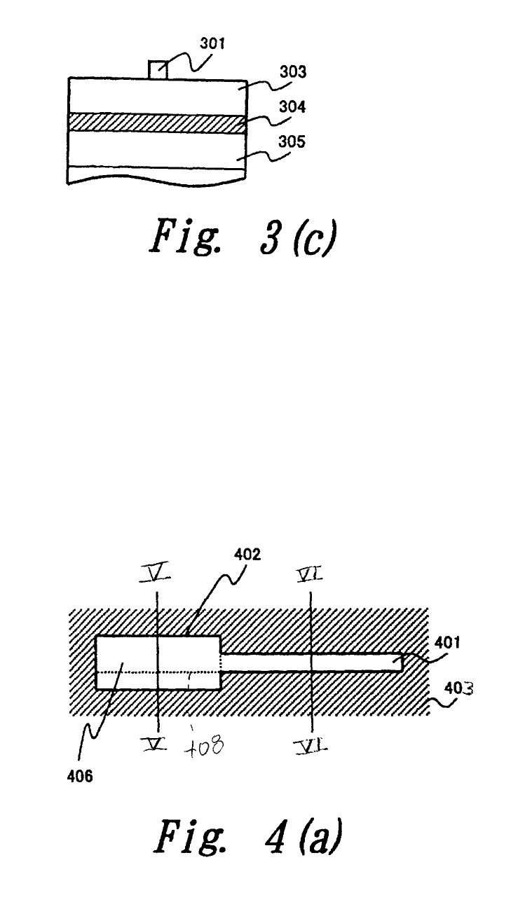

FIG. 3(a) is a plan view showing the structure in a neighborhood of a pad formed on a circuit board for transmitting signals consistent with a second embodiment of the present invention. FIGS. 3(b) and (c) are sections respectively taken along lines III-III and IV-IV of FIG. 3(a). With reference to FIGS. 3(a) to 3(c), a first layer is a transmission layer composed of a surface layer pattern formed on a dielectric layer 303. The surface layer pattern includes a pattern 301 and a pad 302. A second layer is a ground/power supply layer composed of a ground/power supply plane 304 and a dielectric layer 305. In the sections shown in FIGS. 3(b) and 3(c), the lower layers below the dielectric layer 305 are not shown and only the shape, the position, and the number of holes for impedance matching are different from those of the holes 108 shown in FIG. 1. More particularly, only one hole 306 for impedance matching is formed in the ground/power supply plane 304 below the pad 302. As seen in FIGS. 3(a) and 3(b), the width of the hole 306 is bounded by imaginary lines 308 and 310 made by extending the edges of the pattern 101.

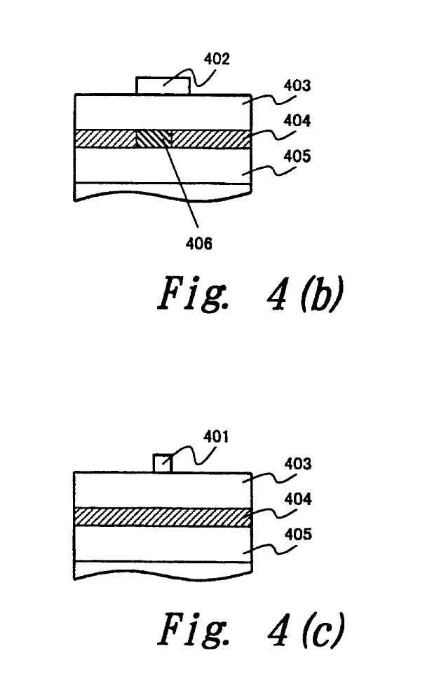

FIG. 4(a) is a plan view showing the structure in a neighborhood of a pad formed on a circuit board for transmitting signals consistent with a third embodiment of the present invention. FIGS. 4(b) and (c) are sections respectively taken along lines V-V and VI-VI of FIG. 4(a). With reference to FIGS. 4(a) to 4(c), a first layer is a transmission layer composed of a surface layer pattern formed on a dielectric layer 403. The surface layer pattern includes a pattern 401 and a pad 402. A second layer is a ground/power supply layer composed of a ground/power supply plane 404 and a dielectric layer 405. In the sections shown in FIGS. 4(b) and 4(c), the lower layers below the dielectric layer 405 are not shown and only the shape, the position, and the number of holes for impedance matching are different from those of the holes 108 shown in FIG. 1. More particularly, only one hole 406 for impedance matching is formed in the ground/power supply plane 404 below the pad 402. The hole 406 is formed to have one edge bound by an imaginary line 408 made by extending the edge of the pattern 401. The other edge of the hole 406 corresponds to the edge of the pad 402.

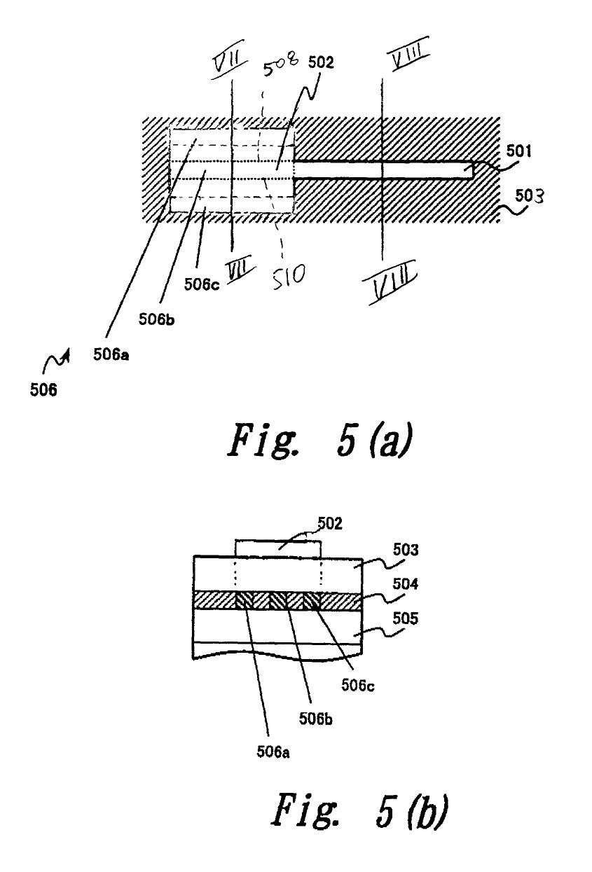

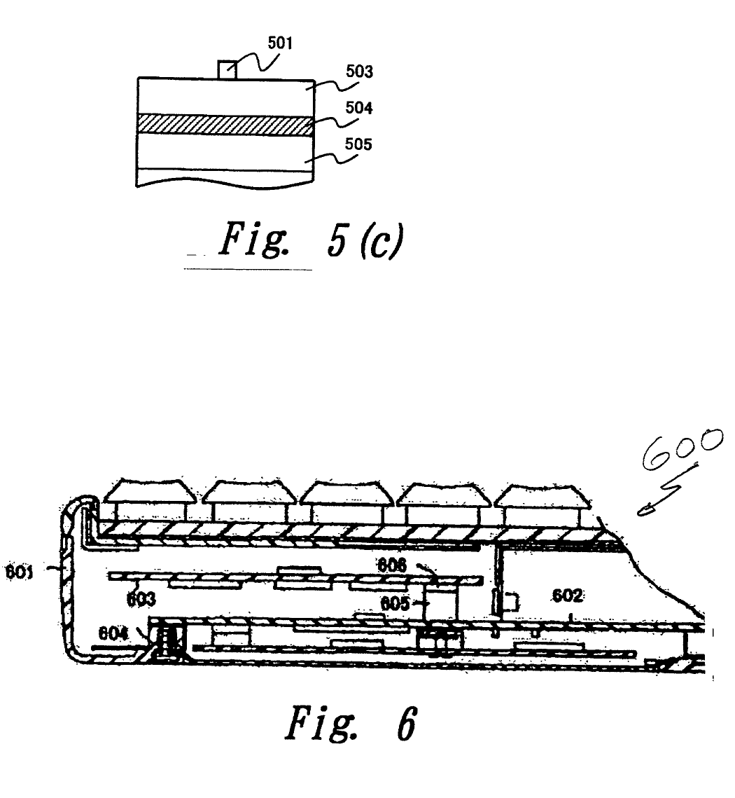

FIG. 5(a) is a plan view showing the structure in a neighborhood of a pad formed on a circuit board for transmitting signals consistent with a fourth embodiment of the present invention. FIG. 5(b) and (c) are sections respectively taken along lines VII-VII and VIII-VIII of FIG. 5(a). With reference to FIGS. 5(a) to 5(c), a first layer is a transmission layer composed of a surface layer pattern formed on a dielectric layer 503. The surface layer pattern includes a pattern 501 and a pad 502. A second layer is a ground/power supply layer composed of a ground/power supply plane 504 and a dielectric layer 505. In the sections shown in FIGS. 5(b) and 5(c), the lower layers below the dielectric layer 505 are not shown and only the shape, the position, and the number of holes for impedance matching are different from those of the holes 108 shown in FIGS. 1(a) and 1(b). More particularly, the structure has three holes 506 for impedance matching, e.g., holes 506a, 506b, and 506c. The hole 506b is formed in the ground/power supply plane 504 below the pad 502 and is within broken imaginary lines 508 and 510 made by extending the edges oft he pattern 501. Each oft he holes 506a and 506c is formed in the ground/power supply plane 504 below the pad 502 outside those imaginary lines 508 and 510, respectively. Further, each of the holes 506a and 506c has an outer edge aligned with a corresponding edge of the pad 502, as indicated by the broken lines in FIG. 5(b). Also, as shown in FIG. 5(a), the holes 506a, 506b, and 506c are parallel to each other.

FIG. 6 is a section showing a circuit board, mounted in a computer, for transmitting signals consistent with embodiments of the present invention. As shown in FIG. 6, a computer 600 includes a body 601 having a shape of a hollow box and containing circuit boards 602 and 603 mounted therein. The circuit board 602 is fixed to the body 601 by means of a supporting structure 604 provided in the body 601. The circuit board 603 is fixed to the circuit board 602 by means of a stacking connector 605, and electrically connected via a connector 606. At least one of circuit boards 602 and 603 includes a transmission line and pad structure such as illustrated in the embodiments herein, and includes a hole or holes in a ground/power supply plane below the pad to provide impedance matching. As a result, the precision with which the computer 600 operates can be improved by mounting therein a circuit board having good transmission integrity of high-speed signals.

Embodiments consistent with the present invention include a hole for impedance matching formed in the ground/power supply plane below the pad, the hole extending substantially parallel with the direction in which the pattern leads or extends from the pad, namely, the propagation direction of transmission signals. As a result, the impedance of the pad can be made to match that oft he pattern along the travel direction. Therefore, as long as the hole for impedance matching is substantially parallel with the travel direction of transmission signals, the shape, the position, and the number of the hole can be properly adjusted to obtain a desired impedance that matches the impedance of the pattern. Further, holes consistent with the present invention formed under or below the pad include holes directly below or under the pad or offset from the location of the pad.

As described above in detail, according to these embodiments, the hole for impedance matching is formed in the ground/power supply plane below the pad in parallel with the propagation direction of transmission signals to suppress impedance mismatch and reduce the reflection. As a result, the transmission integrity of high-speed signals can be improved.

It will be apparent to those skilled in the art that various modifications and variations can be made in the apparatus and method of the present invention without departing from the spirit or scope of the invention. Thus, it is intended that the present invention cover the modifications and variations of this invention provided they come within the scope of the appended claims and their equivalents.

What is claimed is:

1. A circuit board for transmitting signals, comprising:
a dielectric layer;
a signal line configured as a pattern on the dielectric layer to transmit the signals;
a pad formed on the dielectric layer, the pattern connected to and extending away from the pad; and
a ground/power supply layer formed under the dielectric layer and having a hole below the pad, the hole extending in a direction substantially parallel with a direction of the pattern extending away from the pad.

2. The circuit board of claim 1, wherein:
the hole is rectangular and formed outside an imaginary line extending the pattern.

3. The circuit board of claim 1, wherein:
the hole is rectangular and has a width wider than that of the pattern and narrower than that of the pad.

4. The circuit board of claim 1, wherein:
the hole comprises a pair of rectangular holes formed below the pad outside imaginary lines extending the pattern and a third rectangular hole formed between the imaginary lines.

5. The circuit board of claim 1, wherein:
the hole comprises a pair of rectangular holes formed below the pad outside imaginary lines extending the pattern.

6. The circuit board of claim 5, wherein:
each of the holes spreads in a width direction of the pad at a junction of the pattern and the pad.

7. The circuit board of claim 5, wherein:
each of the holes narrows in a width direction of the pad at an edge of the pad remote from a junction of the pattern and the pad.

8. The circuit board of claim 1, wherein:
the hole is rectangular and formed between imaginary lines extending the pattern.

9. A method for producing a circuit board for transmitting signals, comprising:
forming a dielectric layer;
forming a signal line configured as a pattern on the dielectric layer to transmit the signals;
forming a pad on the dielectric layer and connected to the pattern; and
forming a ground/power supply layer under the dielectric layer including a hole below the pad, the hole extending in a direction substantially parallel with a direction of the pattern extending away from the pad.

10. The method of claim 9, wherein forming the ground/power supply layer includes:
forming the hole as a rectangular hole outside an imaginary line extending the pattern.

11. The method of claim 9, wherein forming the ground/power supply layer includes:
forming the hole as a rectangular hole having a width wider than that of the pattern and narrower than that of the pad.

12. The method of claim 9, wherein forming the ground/power supply layer includes:
forming the hole as a pair of rectangular holes below the pad outside imaginary lines extending the pattern and a third rectangular hole formed between the imaginary lines.

13. The method of claim 9, wherein forming the ground/power supply layer includes:
forming a pair of rectangular holes below the pad outside imaginary lines extending the pattern.

14. The method of claim 9, wherein forming the ground/power supply layer includes:
forming the hole as a rectangular hole between imaginary lines extending the pattern.

15. An electronic device, comprising:
a body for mounting circuit elements, and a circuit board mounted in the body and including a signal transmitting line on a surface thereof, the circuit board including:
a dielectric layer having an upper surface and a lower surface ;
a pattern formed on the upper surface of the dielectric layer, the pattern comprising the signal transmission line via which signals are transmitted;
a pad formed on the upper surface of the dielectric layer and connected to the pattern, the pad having a width wider than that of the pattern; and
a ground/power supply layer formed on the lower surface oft he dielectric layer and having at least one hole below the pad, the hole being rectangular and longer in a direction substantially parallel with a direction of the pattern extending away from the pad.

16. The device of claim 15, wherein:
the hole is a rectangular hole and formed outside an imaginary line extending the pattern.

17. The device of claim 15, wherein
the hole is rectangular and has a width wider than that of the pattern and narrower than that of the pad.

18. The device of claim 15, wherein:
the hole comprises a pair of rectangular holes formed below the pad outside imaginary lines extending the pattern and a third rectangular hole formed between the imaginary lines.

19. The device of claim 15, wherein:
the signals are high-speed signals.

20. The device of claim 15, wherein:
the hole comprises a pair of rectangular holes formed below the pad outside imaginary lines extending the pattern.

21. The device of claim 20, wherein:
each of the holes spreads in a width direction of the pad at a junction of the pattern and the pad.

22. The device of claim 20, wherein:
each of the holes narrows in a width direction of the pad at an edge of the pad remote from a junction of the pad.

23. The device of claim 15, wherein:
the hole is rectangular and formed between imaginary lines extending the pattern.
